(19) United States
(12) Patent Application Publication
(10) Pub. No.: US 2014/0151734 A1
(43) Pub. Date: Jun. 5, 2014

(54) LIGHT-EMITTING DEVICE AND METHOD FOR MANUFACTURING SAME

(71) Applicant: PANASONIC CORPORATION, Osaka (JP)

(72) Inventors: Kenichi ITO, Osaka (JP); Yoshiyuki IDE, Kagoshima (JP); Hideaki USUKUBO, Kagoshima (JP); Koji NAKATSU, Kagoshima (JP); Takafumi UCHIDA, Kagoshima (JP)

(73) Assignee: PANASONIC CORPORATION, Osaka (JP)

(21) Appl. No.: 14/147,426

(22) Filed: Jan. 3, 2014

Related U.S. Application Data
(63) Continuation of application No. PCT/JP2012/003913, filed on Jun. 14, 2012.

(30) Foreign Application Priority Data
Jul. 19, 2011 (JP) 2011-158000

(51) Int. Cl. H01L 33/52; H01L 33/58

(52) U.S. Cl. CPC H01L 33/52; H01L 33/58
USPC 257/98

(57) ABSTRACT

A light-emitting device includes: a substrate; a light-emitting element mounted on the substrate, with a surface opposite to a light-emitting surface facing the substrate; a first resin encapsulant which covers the light-emitting element such that at least part of the light-emitting surface is exposed; and a second resin encapsulant provided on and in contact with the first resin encapsulant and the light-emitting surface. The first resin encapsulant contains a light reflective material. The second resin encapsulant has a function of converting first light emitted by the light-emitting element into second light of different wavelength, and a function of mixing the first light and the second light.

### CROSS-REFERENCE TO RELATED APPLICATIONS

This is a continuation of International Application No. PCT/JP2012/003913 filed on Jun. 14, 2012, which claims priority to Japanese Patent Application No. 2011-158000 filed on Jul. 19, 2011. The entire disclosures of these applications are incorporated by reference herein.

### BACKGROUND

The present disclosure relates to light-emitting devices and methods for manufacturing the light-emitting devices, and specifically relates to light-emitting devices having a resin encapsulant which transmits light from a light-emitting element, and methods for manufacturing the light-emitting devices.

Light-emitting diodes (LEDs), which are small with good power efficiency and capable of emitting light of various colors due to light wavelength conversion materials, are used as light sources for various purposes. In particular, LEDs have been commercialized as an illumination light source with less power consumption and longer life in place of fluorescent lamps, and also have been commercialized as a light source of flood lamps, such as vehicle's headlights and camera's flashlights.

Light-emitting devices such as LEDs include a light reflecting member around a light-emitting element on a substrate so that light radiated from the light-emitting element in various directions can be efficiently radiated outside the light-emitting device. Further, it is possible to emit light of a desired hue by adhering a light transmissive member containing a wavelength conversion material, such as a phosphor pigment, to a light-emitting surface of the light-emitting element (see, e.g., Japanese Unexamined Patent Publication No. 2010-192629).

### SUMMARY

However, in the above-described conventional light-emitting devices, it is necessary to adhere the light transmissive member, which is prepared beforehand in the form of chip, to the light-emitting surface using an adhesive material. Since the shape and the location of the light transmissive member significantly affect the light distribution angle dependence of chromaticity, the light transmissive member needs to be formed and attached with high accuracy. Moreover, the light transmissive member needs to be thin and small, and needs to be made of a material with a certain degree of hardness. Thus, the light transmissive member is formed, for example, by sintering a mixture of a wavelength conversion material and alumina. The linear expansion coefficient differs between the light transmissive member made of an inorganic material with high hardness, and an encapsulant resin by which the light-emitting device is encapsulated. This may lead to easy detachment of the light transmissive member, and result in a reduction in reliability of the light-emitting device. In addition, since the light transmissive member needs to be prepared in advance and needs to be adhered, it may increase manufacturing costs.

The present disclosure was made to solve the above problems, and is intended to provide a light-emitting device with chromaticity uniformity and high reliability.

To achieve the above objective, a semiconductor light-emitting device of the present disclosure includes a second resin encapsulant having a function of converting a wavelength of light and a function of diffusing and mixing the light.

Specifically, a light-emitting device of the present disclosure includes; a substrate; a light-emitting element mounted on the substrate, with a surface opposite to a light-emitting surface facing the substrate; a first resin encapsulant which covers the light-emitting element such that at least part of the light-emitting surface is exposed; and a second resin encapsulant provided on and in contact with the first resin encapsulant and the light-emitting surface, wherein the first resin encapsulant contains a light reflective material, and the second resin encapsulant converts part of first light emitted by the light-emitting element into second light having a different wavelength, and mixes the first light and the second light.

The light-emitting device of the present disclosure includes a second resin encapsulant provided on and in contact with the first resin encapsulant and the light-emitting surface. The second resin encapsulant converts part of first light emitted by the light-emitting element into second light having a different wavelength. Thus, unlike the case where a light transmission member containing a light wavelength conversion material is attached to a light-emitting surface, it is possible to make the coefficients of linear expansion of the first resin encapsulant and the second resin encapsulant approximately the same, which can increase reliability. Further, since it is not necessary to provide another member by adhering it with an adhesive material, formation steps can be simplified and costs can be reduced. Moreover, since it is not necessary to provide an adhesive material layer, which causes stray light, on the light-emitting surface, variations in chromaticity can be reduced.

In the light-emitting device of the present disclosure, the second resin encapsulant may include a first layer containing a light wavelength conversion material which absorbs the first light and emits the second light, and a second layer provided on the first layer and containing a light diffusing material which diffuses the first light and the second light.

In this case, the second resin encapsulant may include a transparent resin layer provided under the first layer and touching the light-emitting surface. Further, the second resin encapsulant may include a light diffusion layer provided under the first layer, touching the light-emitting surface, and containing a light diffusing material.

In the light-emitting device of the present disclosure, the second resin encapsulant may include a first layer containing a light wavelength conversion material which absorbs first light and emits second light, and having a groove which surrounds the light-emitting element, and a light reflective layer containing a light reflective material and filling the groove.

In this case, the second resin encapsulant may include a second layer provided on the first layer and containing a light diffusing material which diffuses the first light and the second light.

In the light-emitting device of the present disclosure, the second resin encapsulant may include a third layer containing a light wavelength conversion material which absorbs first light and emits second light, and a light diffusing material which diffuses the first light and the second light.

In this case, the third layer may include a groove which surrounds the light-emitting element, and the second resin encapsulant may include a light reflective layer filling the groove and containing a light reflective material.

Further, the second resin encapsulant may include a fourth layer provided on the third layer and containing a light diffusing material.

In the light-emitting device of the present disclosure, the substrate may be provided with a substrate terminal; the light-emitting element may be provided with an element electrode on a surface opposite to the light-emitting surface; and the substrate terminal and the element electrode may be connected by a metal bump.

The light-emitting device of the present disclosure may further include a protection element mounted on the substrate, and the first resin encapsulant may cover an upper surface of the protection element. Further, the upper surface of the protection element may touch the second resin encapsulant.

A method for manufacturing a light-emitting device of the present disclosure includes: a step (a) of placing a light-emitting element on a substrate, with a light-emitting surface facing upward; after the step (a), a step (b) of forming a first resin encapsulant which contains a light reflective material and covers the light-emitting element such that at least part of the light-emitting surface is exposed; and a step (c) of forming a second resin encapsulant on and in contact with the first resin encapsulant and the light-emitting surface, the second resin encapsulant converting part of first light emitted by the light-emitting element into second light having a different wavelength, and mixing the first light and the second light.

In the method of manufacturing the light-emitting device of the present disclosure, the step (c) may include a step of forming a first layer containing a light wavelength conversion material which absorbs the first light and emits the second light, and a step of forming, on the first layer, a second layer containing a light diffusing material which diffuses the first light and the second light.

In this case, the step (c) may include a step of forming a transparent resin layer before forming the first layer, and may include a step of forming a light diffusion layer containing a light diffusing material before forming the first layer.

In the method of manufacturing the light-emitting device of the present disclosure, the step (c) may include a step of forming a first layer containing a light wavelength conversion material which absorbs the first light and emits the second light, a step of forming, in the first layer, a groove which surrounds the light-emitting element, and a step of filling the groove with a light reflective layer containing a light reflective material.

In this case, the step (c) may include a step of forming, on the first layer, a second layer containing a light diffusing material which diffuses the first light and the second light.

In the method of manufacturing the light-emitting device of the present disclosure, the step (c) may include a step of forming a third layer containing a light wavelength conversion material which absorbs the first light and emits the second light, and a light diffusing material which diffuses the first light and the second light.

In this case, the step (c) may include a step of forming a groove which surrounds the light-emitting element in the third layer, and a step of filling the grove with a light reflective layer containing a light reflective material.

The step (c) may include a step of forming, on the third layer, a fourth layer which diffuses the first light and the second light.

In the method of manufacturing the light-emitting device of the present disclosure, in the step (a), a substrate terminal provided on the substrate and an element electrode provided on a surface of the light-emitting element which is opposite to the light-emitting surface may be connected to each other via a metal bump.

The method for manufacturing the light-emitting device of the present disclosure may further include, before the step (b), a step (d) of placing a protection element on the substrate, wherein in the step (b), the first resin encapsulant may be formed so as to cover an upper surface of the protection element. Further, the first resin encapsulant may be formed so as to expose the upper surface of the protection element.

According to a light-emitting device of the present disclosure and a method for manufacturing the light-emitting device, it is possible to provide a light-emitting device with chromaticity uniformity and high reliability.

### BRIEF DESCRIPTION OF THE DRAWINGS

FIG. 1 is a cross section of a light-emitting device of an embodiment.

FIGS. 2A-2C show cross sections illustrating a method for manufacturing the light-emitting device of the embodiment in the order of steps.

FIGS. 3A-3B show cross sections illustrating a method for manufacturing the light-emitting device of the embodiment in the order of steps.

FIG. 4 is a cross section of a variation of the light-emitting device of an embodiment.

FIG. 5 is a cross section of a variation of the light-emitting device of an embodiment.

FIG. 6 is a cross section of a variation of the light-emitting device of an embodiment.

FIG. 7 is a cross section of a variation of the light-emitting device of an embodiment.

FIG. 8 is a cross section of a variation of the light-emitting device of an embodiment.

FIG. 9 is a cross section of a variation of the light-emitting device of an embodiment.

FIGS. 10A-10C show cross sections illustrating a method for manufacturing a variation of the light-emitting device of the embodiment in the order of steps.

FIG. 11 is a cross section of a variation of the light-emitting device of an embodiment.

FIG. 12 is a cross section of a variation of the light-emitting device of an embodiment.

FIG. 13 is a cross section of a variation of the light-emitting device of an embodiment.

FIG. 14 is a cross section of a variation of the light-emitting device of an embodiment.

FIG. 15 is a cross section of a variation of the light-emitting device of an embodiment.

### DETAILED DESCRIPTION

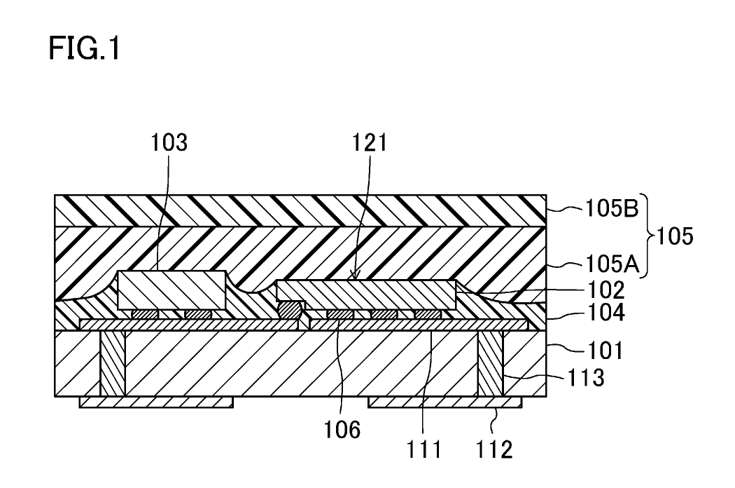

As illustrated in FIG. 1, a light-emitting device of an embodiment includes a light-emitting element 102 and a protection element 103 which are placed on a substrate 101, and a first resin encapsulant 104 and a second resin encapsulant 105 sequentially formed on the substrate 101 to encapsulate the light-emitting element 102 and the protection element 103.

The substrate 101 may be an insulating substrate made of ceramics or glass epoxy resin, for example, and having a thickness of about 0.3 mm to 0.5 mm. In particular, a ceramics substrate is preferable as having a high resistance to heat and weather. Examples of the ceramics substrate may include an aluminum nitride (AlN) substrate and an aluminum oxide (Al₂O₃) substrate, which may be appropriately chosen depending on necessary heat dissipation properties and material costs.

The substrate 101 is provided with a substrate terminal 111 on its element placement surface (i.e., an upper surface), an external connection terminal 112 on a surface (i.e., a back surface) opposite to the element placement surface, and a through via 113 connecting the substrate terminal 111 and the external connection terminal 112. Each of the substrate terminal 111 and the external connection terminal 112 may be made of a conductive material, such as copper, nickel, gold, silver, or tungsten. Further, the uppermost surface may be gold plated, for example. The through via 113 may be made of a conductive material, such as copper, tungsten or silver.

The light-emitting element 102 is mounted on the substrate 101, with a light-emitting surface 121 facing upward. The light-emitting element 102 may be nitride-based light-emitting diode, for example. The nitride-based light-emitting diode may have a configuration in which, for example, a nitride semiconductor layer (not shown) including a light-emitting layer made of gallium nitride (GaN), etc., and an element electrode (not shown) are provided on a support substrate (not shown). The support substrate may be a sapphire substrate, a gallium nitride substrate, an aluminum gallium nitride substrate, an aluminum nitride substrate, a silicon carbide substrate, etc. In particular, a substrate made of a nitride semiconductor material is preferable since there is only a little difference in refractive index between the substrate made of a nitride semiconductor material and the light-emitting layer made of GaN, or a silicon carbide substrate is preferable. The element electrode may be made of gold or aluminum, etc. The size of the light-emitting element 102 may be appropriately decided according to necessary light quantity, but may have a thickness of about 0.1 mm, and one side thereof may be about 1 mm.

The light-emitting surface 121 of the light-emitting element 102 is a side facing the support substrate, and the element electrode is connected to the substrate terminal 111 of the substrate 101 via a bump 106. The bump 106 may be made of a conductive material which is favorably connected to the element electrode and the substrate terminal 111. For example, gold, gold-tin, solder, or a conductive polymer may be used. In particular, a gold bump is preferable in view of its connection reliability.

The protection element 103 is provided to prevent an excessive voltage application to the light-emitting element 102. For example, the protection element 103 may be a Zener diode, a diode, a varistor, a resistance element, or a capacitor element. Alternatively, these elements may be combined. In the present embodiment, the protection element 103 is made, for example, of Si, GaAs, or Ge having a thickness of about 0.1 mm to 0.2 mm, and an electrode of the protection element 103 is connected to the substrate terminal 111 via a bump 106. In the present embodiment, the protection element 103 is connected anti-parallel to the light-emitting element 102. The protection element 103 may be provided as necessary.

The first resin encapsulant 104 covers the surfaces except the light-emitting surface 121 of the light-emitting element 102, so that the light-emitting surface 121 is exposed. The first resin encapsulant 104 may be a resin mixed with a light reflective material in powder form.

The resin used as the first resin encapsulant 104 may be a silicone resin, an epoxy resin, or an acrylic resin, etc. A silicone resin, which has a high resistance to light, is particularly preferable. Among silicone resins, a phenyl silicone resin, which is high in stiffness and has a high resistance to light and heat, is particularly preferable. Examples of the light reflective material may include a titanium oxide (TiO₂), silver, a zirconium oxide, potassium titanate (K₂O₆TiO₂), an aluminum oxide, boron nitride or aluminum silicate (Al₆O₁₃Si₂), talc (SiO₂—MgO system), kaolin (SiO₂—Al₂O₃ system), etc. In particular, TiO₂, which has a high reflection coefficient, is preferable. The content of the light reflective material in the resin may be about 20 wt % to 70 wt %. The higher the content of the light reflective material, the higher the reflection coefficient is, and the luminance of the light-emitting device can be increased. However, if the content of the light reflective material is too high, the viscosity of the resin is increased, which results in difficulty in filling a gap between the substrate 101 and the light-emitting element 102. Thus, the content of the light reflective material may be appropriately decided according to a method for forming the first resin encapsulant 104.

Since the first resin encapsulant 104 containing the light reflective material covers the surfaces except the light-emitting surface 121 of the light-emitting element 102, it is possible to reflect light emitted in directions other than upward from the light-emitting element 102. This can increase the luminous efficiency of the light-emitting device, and narrow a light-emitting angle.

The second resin encapsulant 105 is formed so as to touch the upper surface of the first resin encapsulant 104 and the light-emitting surface 121 of the light-emitting element 102. The second resin encapsulant 105 includes sequentially formed layers, i.e., a first layer 105A containing a light wavelength conversion material, and a second layer 105B containing a light diffusing material.

The first layer 105A may be made of a resin mixed with a light wavelength conversion material in powder form which converts part of light of a first wavelength emitted from the light-emitting element 102 into light of a second wavelength different from the first wavelength. The light wavelength conversion material may be appropriately decided according to the first wavelength and the second wavelength. For example, the light wavelength conversion material may be powders of a phosphor, such as yttrium aluminum garnet (YAG) or BOS(4-1(Ba,Sr)₂SiO₄:Eu). The resin may contain silicone, epoxy, or acrylic resin as a base resin. Among silicone resins, a phenyl silicone resin, which is high in stiffness and has a high resistance to light and heat, is particularly preferable.

In the case where the light of the first wavelength emitted from the light-emitting element 102 is blue light, the first layer 105A made of a material mixed with a phosphor which converts the blue light into yellow light may be provided, thereby making it possible to generate light of the second wavelength, i.e., yellow light. Further, white light can be generated by mixing the blue light as the light of the first wavelength, and the yellow light as the light of the second wavelength.

The thickness of the first layer 105A, and the content of the light wavelength conversion material in the first layer 105A, etc., may be appropriately changed. However, for example, if the thickness of the first layer 105A is about 0.1 mm, the content of the light wavelength conversion material may be set to 30 wt % or so.

The second layer 105B may be made of a resin mixed with a light diffusing material which diffuses light of the first wavelength and the light of the second wavelength. The light diffusing material may be powders of silicon oxide (SiO₂), etc. The resin may contain silicone, epoxy, or acrylic resin as a base resin. Among silicone resins, a phenyl silicone resin, which is high in stiffness and has a high resistance to light and heat, is particularly preferable.

Since the second layer 105B containing the light diffusing material is formed on the first layer 105A containing the light wavelength conversion material, it is possible to efficiently diffuse and mix the light of the first wavelength and the light of the second wavelength. Since the first layer 105A is provided across a large area, variations in chromaticity can be reduced even if light passing through the first layer 105A which contains the light wavelength conversion material has significantly different optical paths.

In the second layer 105B, the content of the light diffusing material in a resin may be about 20 wt % to 70 wt %. The higher the content of the light diffusing material, the more the effect of increasing color uniformity. However, if the content of the light diffusing material is too high, it becomes difficult to form the second layer 105B. For example, if the thickness of the second layer 105B is about 0.1 mm, the content of the light diffusing material may be about 60 wt %.

By forming the second layer 105B using a material whose refractive index is higher than the refractive index of the first layer 105A, it is possible to narrow the light-emitting angle. For example, a dimethyl silicone resin whose refractive index is 1.41 may be used as the first layer 105A, and a phenyl silicone resin whose refractive index is 1.53 may be used as the second layer 105B.

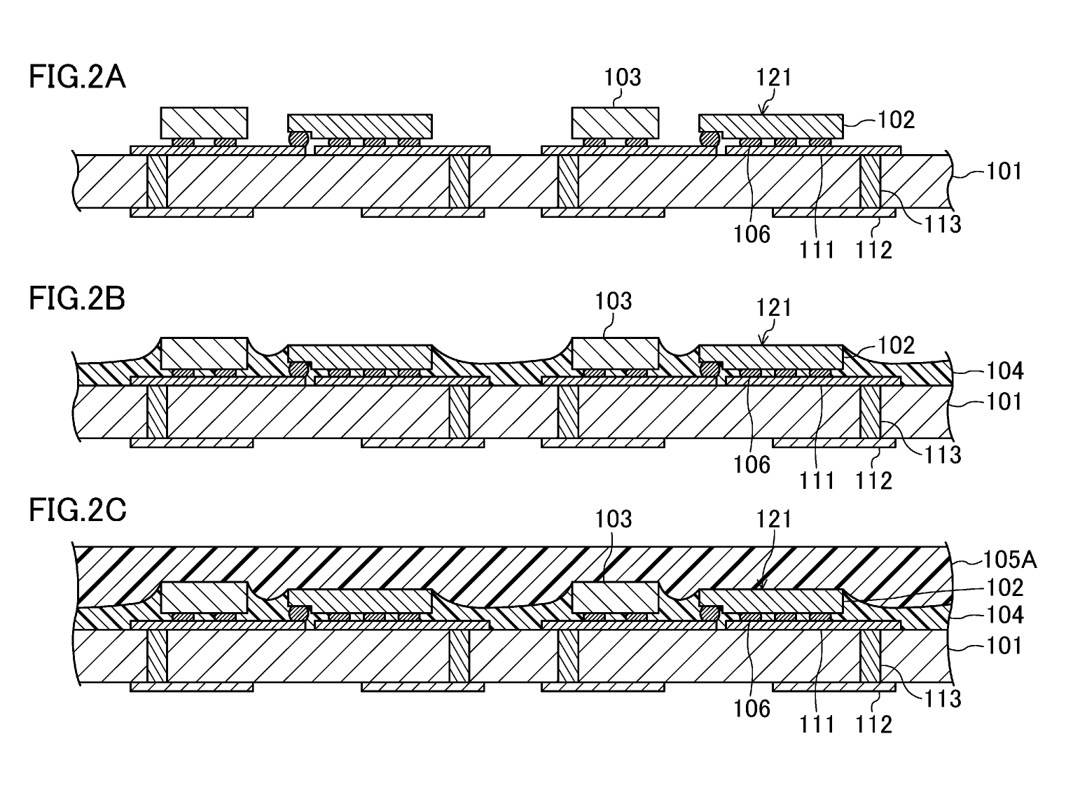

A method for manufacturing the light-emitting device of the present embodiment will be described below. First, as illustrated in FIG. 2A, a light-emitting element 102 and a protection element 103 are fixed on the substrate 101. Known techniques may be used to fix the light-emitting element 102 and the protection element 103 on the substrate 101. For example, first, bumps 106 are formed on the substrate terminal 111 of the substrate 101. Specifically, gold bumps may be formed using a wire bonding device. In forming the gold bumps using the wire bonding device, the substrate 101 may be mounted on a heat stage of the wire bonding device by a suction force, and the gold bumps are formed thereafter, with the edge of the substrate 101 fixed with a fixing jig. In forming the gold bumps, the light-emitting element 102 and the protection element 103 may be fixed by thermal compression bonding combined with ultrasonic wave. Before forming the bumps 106, the substrate 101 may be irradiated with argon plasma, etc., to remove organic substances from the surface of the substrate 101.

Next, as illustrated in FIG. 2B, a resin containing a light reflective material is applied to the periphery of the light-emitting element 102, using a syringe, etc., to form a first resin encapsulant 104. The first resin encapsulant 104 is formed so as to expose the light-emitting surface 121 of the light-emitting element 102, and a gap between the substrate 101 and the light-emitting element 102 is filled with the first resin encapsulant 104 due to capillarity. Since light of the light-emitting element 102 can be reflected by the first resin encapsulant 104 having a high reflection coefficient, it is possible to increase the luminous efficiency of the light-emitting element 102 and narrow a light-emitting angle.

Next, as illustrated in FIG. 2C, a first layer 105A containing a light wavelength conversion material is formed on the light-emitting element 102, the protection element 103 and the first resin encapsulant 104. For example, a resin containing a light wavelength conversion material is applied onto the substrate 101 using a syringe, and thereafter, the edge of the substrate 101 is clamped with heated molds, so that the applied resin has a predetermined thickness. After that, final curing is performed on the resin in a curing oven, thereby forming the first layer 105A. The first layer 105A may also be formed by a printing method using a squeegee. In the printing method, the first layer 105A may be printed, with a metal mask pressed against an outer edge of the substrate 101. The first layer 105A may have an uneven thickness if it is formed by a printing method. Thus, after the final curing is performed on the resin, the layer may be ground to control the thickness and increase the flatness of the resin surface.

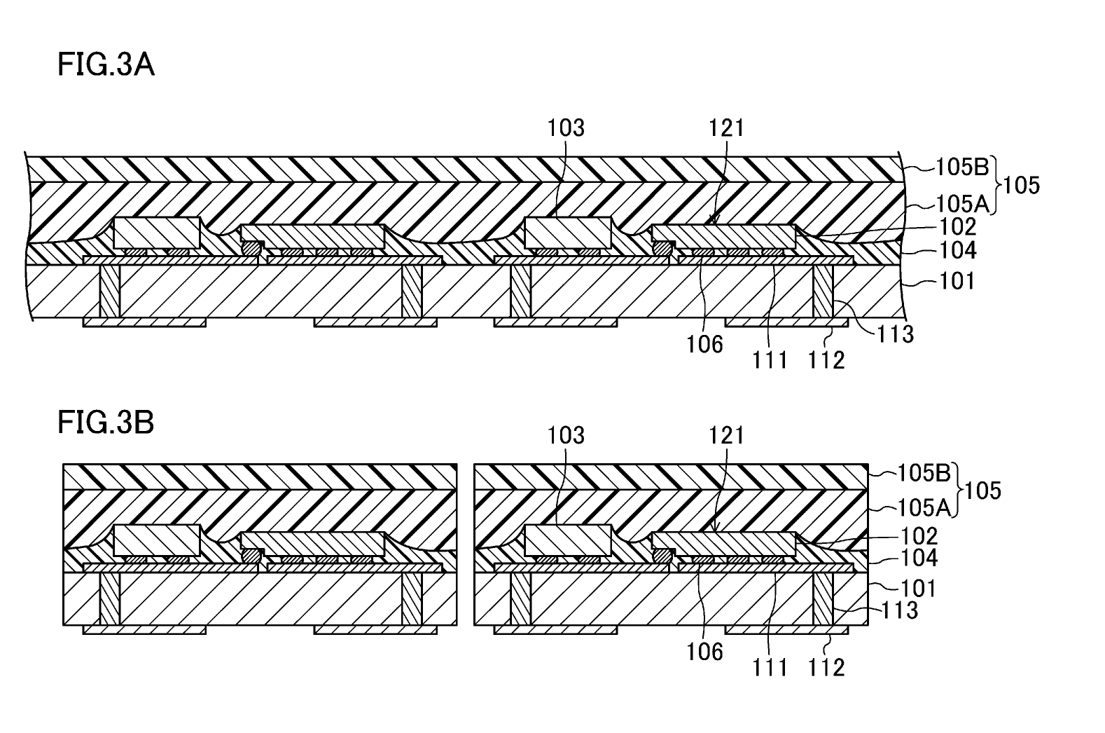

Next, as illustrated in FIG. 3A, a second layer 105B containing a light diffusing material may be formed on the first layer 105A. The second layer 105B may be formed in a similar manner as the first layer 105A.

Next, as illustrated in FIG. 3B, the substrate may be divided into individual light-emitting devices by a dicing machine.

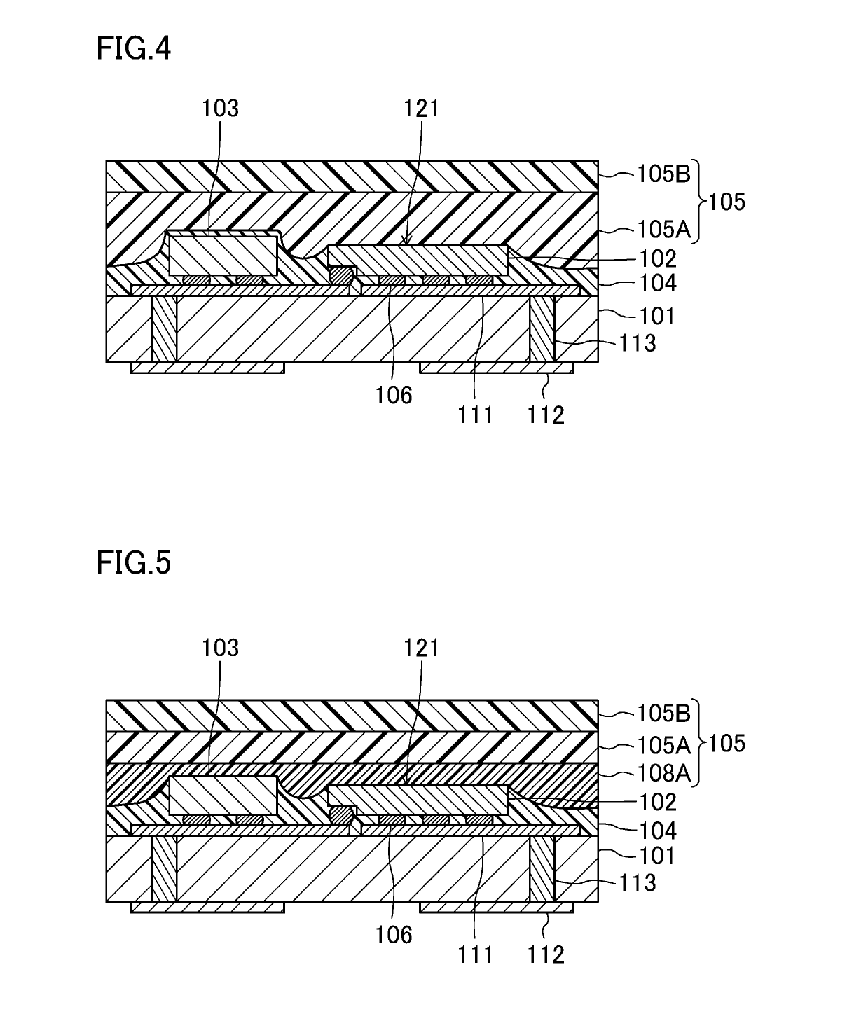

It is preferable that the first resin encapsulant 104 covers the element placement surface of the substrate 101 as much as possible, because optical feedback can be efficiently reflected. However, the element placement surface of the substrate 101 does not have to be entirely covered by the first resin encapsulant 104, and part of the element placement surface may be exposed. In this case, part of the second resin encapsulant 105 touches the substrate 101. Further, the first resin encapsulant 104 may cover at least the side surfaces of the light-emitting element 102, and as illustrated in FIG. 4, the first resin encapsulant 104 may cover the upper surface of the protection element 103. By covering the upper surface of the protection element 103 with the first resin encapsulant 104, it is possible to reflect optical feedback more efficiently.

In the present embodiment, the second resin encapsulant 105 was illustrated as including the first layer 105A containing a light wavelength conversion material and the second layer 105B containing a light diffusing material, but as shown in FIG. 5, a transparent resin layer 108A may be provided under the first layer 105A.

The first layer 105A on the light-emitting surface 121 may have an uneven thickness due to the warpage of the substrate 101, variations in heights of the bumps 106, variations in height of the light-emitting element 102, etc. However, the transparent resin layer 108A provided between the light-emitting element 102 and the first layer 105A can reduce the uneven thickness of the first layer 105A on the light-emitting surface 121, and variations in chromaticity can be reduced.

By forming the first layer 105A using a material whose refractive index is higher than the refractive index of the transparent resin layer 108A, it is possible to narrow the light-emitting angle. For example, a dimethyl silicone resin whose refractive index is 1.41 may be used as the transparent resin layer 108A, and a phenyl silicone resin whose refractive index is 1.53 may be used as the first layer 105A and the second layer 105B.

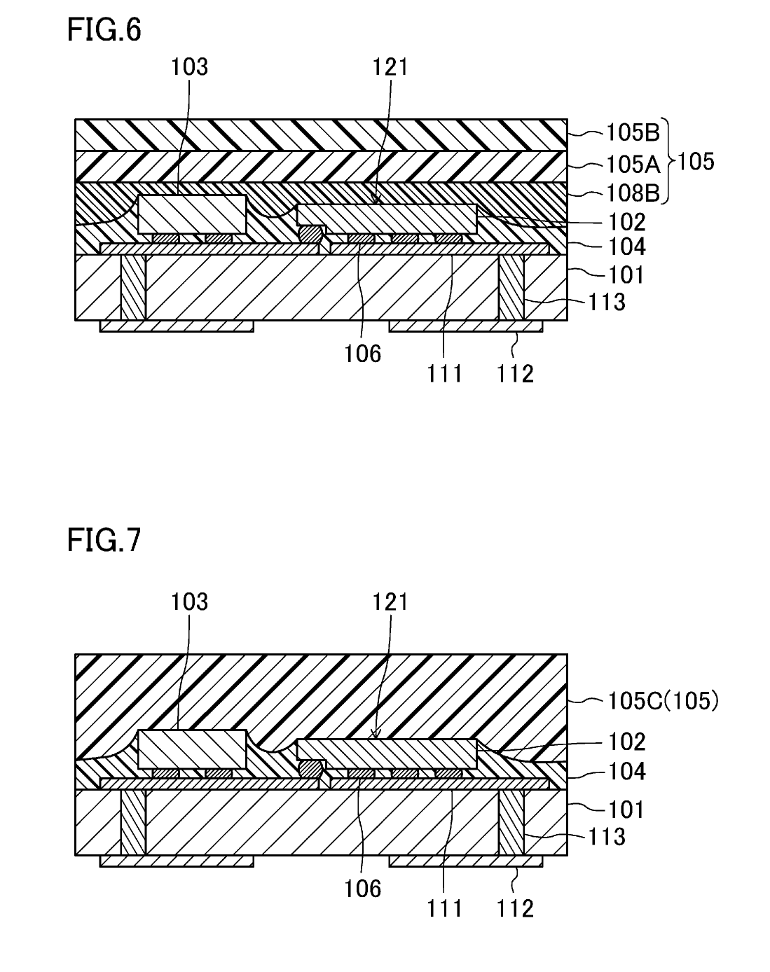

As illustrated in FIG. 6, the transparent resin layer may be replaced with a light diffusion layer 108B containing a light diffusing material, such as SiO₂ powders. Since the light diffusion layer 108B can be formed using the same material as the second layer 105B, commonality of the manufacturing steps is increased and manufacturing costs can be reduced. At least the resin or the light diffusing material may differ between the light diffusion layer 108B and the second layer 105B.

By forming the first layer 105A and the second layer 105B using a material whose refractive index is higher than the refractive index of the light diffusion layer 108B, it is possible to narrow the light-emitting angle. For example, a dimethyl silicone resin whose refractive index is 1.41 may be used as the light diffusion layer 108B, and a phenyl silicone resin whose refractive index is 1.53 may be used as the first layer 105A and the second layer 105B.

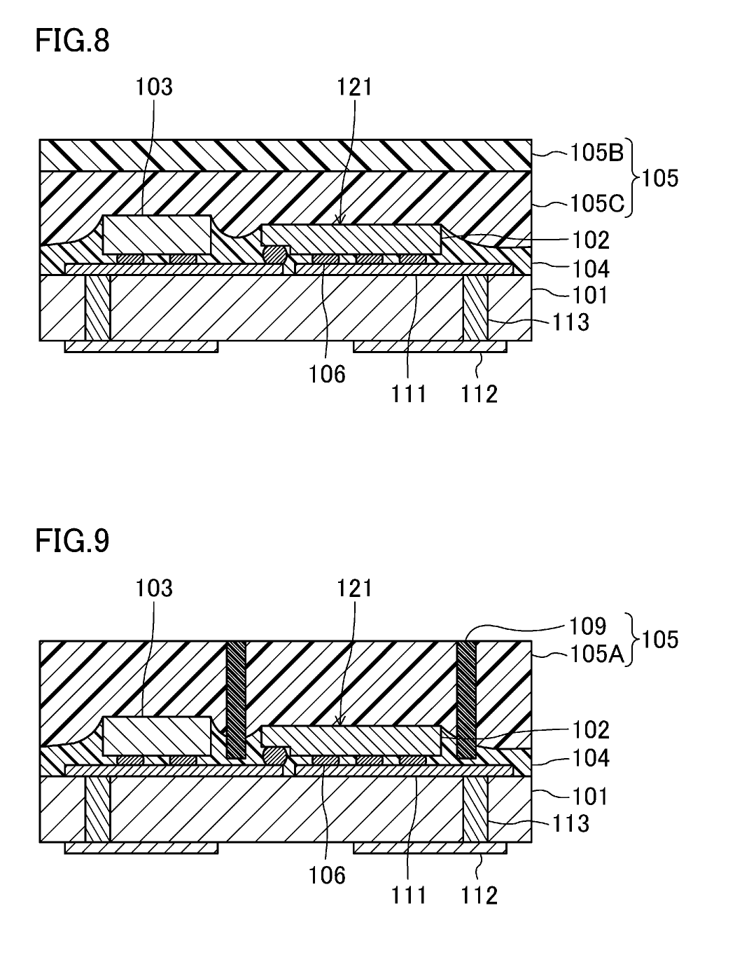

As illustrated in FIG. 7, the second resin encapsulant 105 may be made of a third layer 105C which contains a light wavelength conversion material and a light diffusing material. Forming the second resin encapsulant 105 using the third layer 105C which contains the light wavelength conversion material and the light diffusing material simplifies the formation steps of the second resin encapsulant 105, and reduces the manufacturing costs. As illustrated in FIG. 8, the second layer 105B containing a light diffusing material may be formed on the third layer 105C.

By forming the second layer 105B using a material whose refractive index is higher than the refractive index of the third layer 105C, it is possible to narrow the light-emitting angle. For example, a dimethyl silicone resin whose refractive index is 1.41 may be used as the third layer 105C, and a phenyl silicone resin whose refractive index is 1.53 may be used as the second layer 105B.

The first resin encapsulant 104 may cover the upper surface of the protection element 103 in both cases where the transparent resin layer 108A or the light diffusion layer 108B is provided, and where the second resin encapsulant 105 is made of the third layer 105C which contains the light wavelength conversion material and the light diffusing material. Further, the transparent resin layer 108A or the light diffusion layer 108B may be formed under the third layer 105C which contains the light wavelength conversion material and the light diffusing material.

The second resin encapsulant 105 is configured to convert part of light of the first wavelength which is emitted from the light-emitting element 102 into light of the second wavelength, and diffuse and mix the light of the first wavelength and the light of the second wavelength. Thus, the second resin encapsulant 105 may have a configuration as illustrated in FIG. 9. The second resin encapsulant 105 in FIG. 9 includes a first layer 105A containing a light wavelength conversion material, and a light reflective layer 109 buried in the first layer 105A and containing a light reflective material. The light reflective layer 109 fills a groove formed in the first layer 105A so as to surround the light-emitting element 102. Since the light reflective layer 109 surrounds the light-emitting element 102, it is possible to further narrow the light-emitting angle. Further, since there is no adhesive material layer provided between a resin layer containing a light wavelength conversion material and the light-emitting element 102, there is no possibility of stray light caused by the adhesive material layer. As a result, the luminous efficiency can be increased.

The light reflective layer 109 may be formed in a manner as described below. First, the same steps as in the case where no light reflective layer 109 is provided are taken until the first layer 105A is formed.

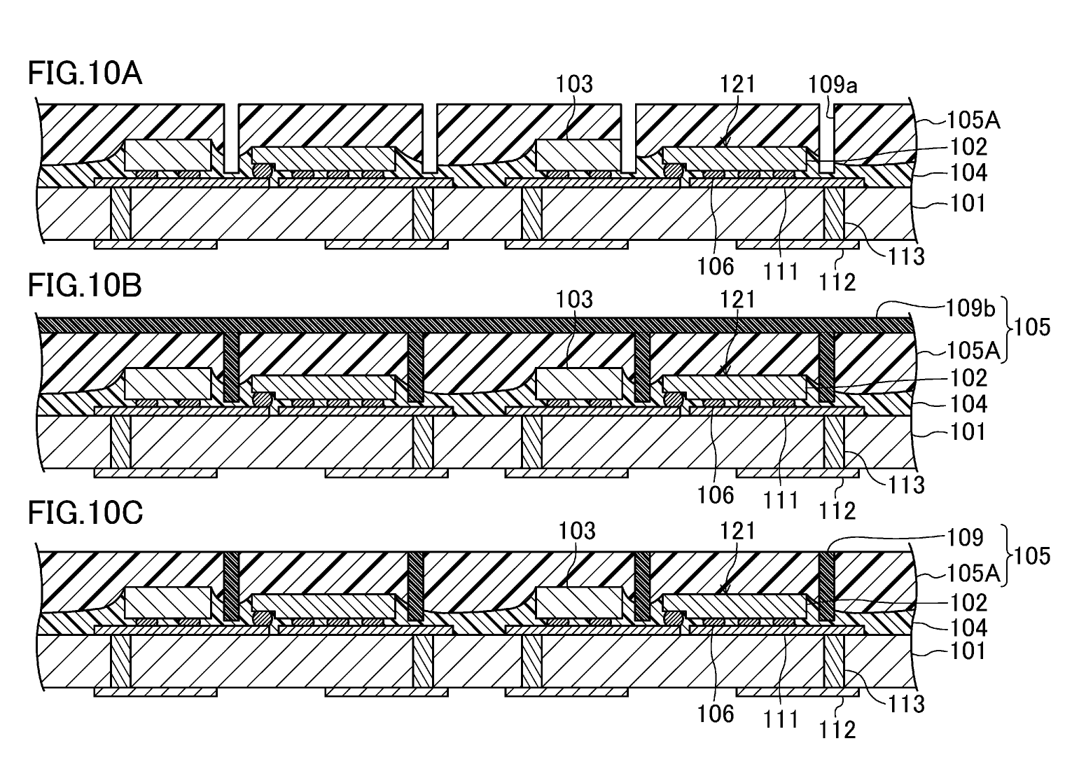

Next, as illustrated in FIG. 10A, part of the first layer 105A is removed to expose the first resin encapsulant 104 using a dicing machine, etc., thereby forming a groove 109a which surrounds the light-emitting element 102.

Next, as illustrated in FIG. 10B, a resin layer 109b containing a light reflective material is formed on the first layer 105A so as to fill the groove 109a. In forming the resin layer 109b, for example, a resin containing a light reflective material is applied on the first layer 105A using a syringe, and thereafter, the edge of the substrate 101 is clamped with heated molds, so that the applied resin has a predetermined thickness. After that, final curing is performed on the resin in a curing oven. The resin layer 109b may also be formed by a printing method using a squeegee. In the printing method, the resin layer 109b may be printed, with a metal mask pressed against an outer edge of the substrate 101.

Next, as illustrated in FIG. 10C, the resin layer 109b is ground by a grinding machine until the first layer 105A is exposed. As a result, the light reflective layer 109 buried in the first layer 105A is obtained. Since the resin layer 109b is ground until the first layer 105A is exposed, the flatness of the upper surface of the second resin encapsulant 105 can be ensured. After that, the substrate is divided into light-emitting devices by a dicing machine.

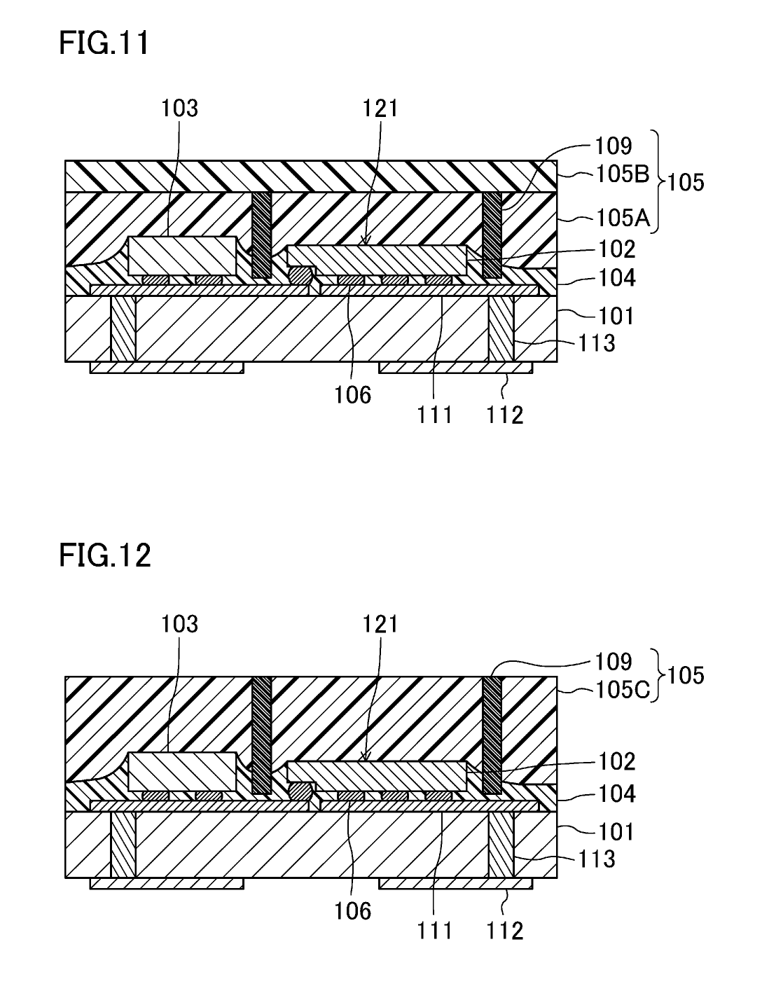

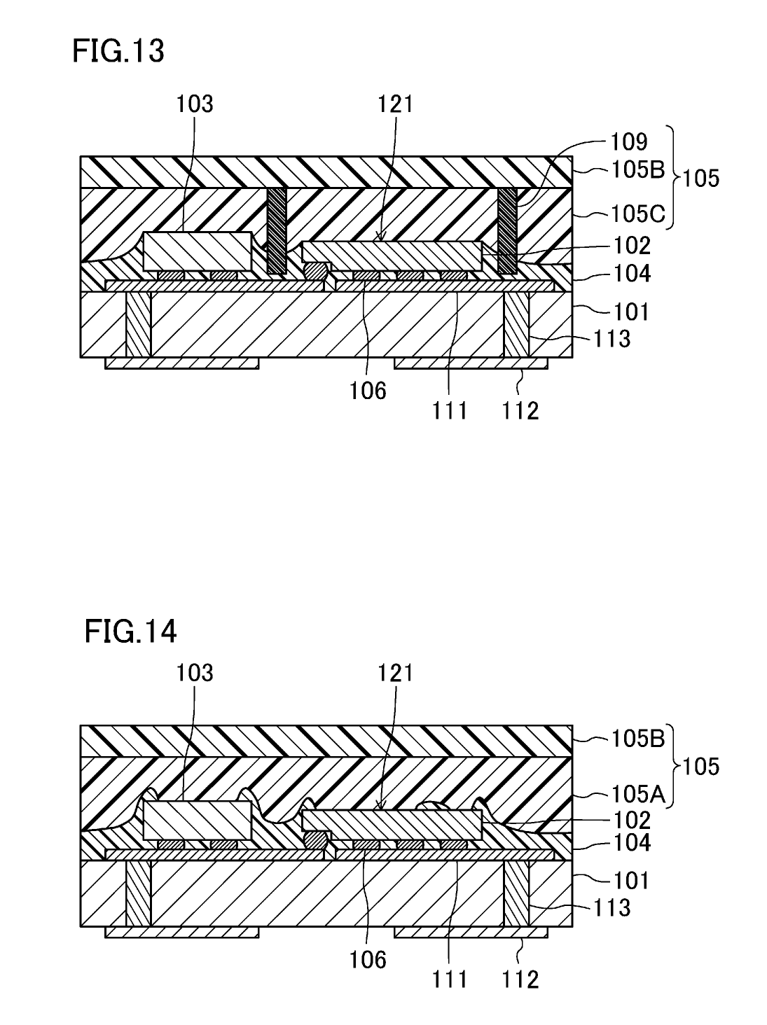

The second layer 105B containing a light diffusing material may be formed on the first layer 105A as illustrated in FIG. 11, also in the case where the light reflective layer 109 is provided. Further, the first layer 105A containing the light wavelength conversion material may be replaced with the third layer 105C containing a light wavelength conversion material and a light diffusing material as illustrated in FIG. 12 and FIG. 13.

The light reflective layer 109 may be made of the same resin and the same light reflective material as the first resin encapsulant 104. Due to this configuration, the manufacturing steps can be simplified. At least the resin or the light reflective material may differ between the light reflective layer 109 and the first resin encapsulant 104.

If the first resin encapsulant 104 and the second resin encapsulant 105 are formed using the same resin, the coefficient of linear expansion can be approximately equal. In the case where the second resin encapsulant 105 includes a plurality of layers, the layers may be made of the same resin. Different resins may also be used if it is possible to make the coefficients of linear expansion approximately the same.

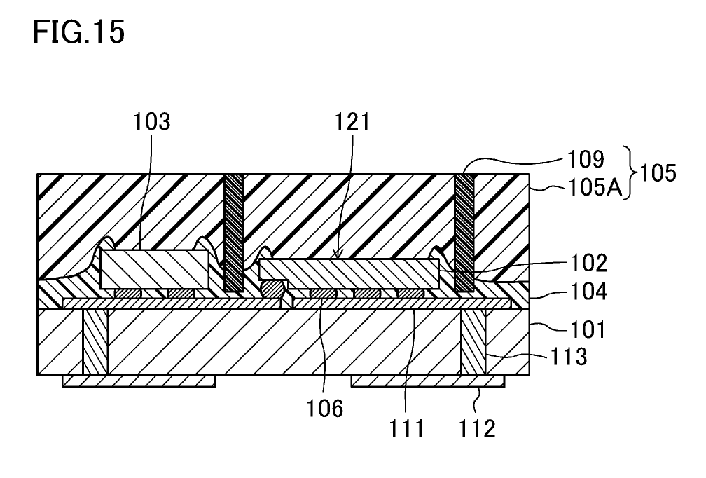

In the drawings, an example is illustrated in which the light-emitting surface 121 of the light-emitting element 102 is entirely exposed. It is ideal that the side surface of the light-emitting element 102 is entirely covered by the first resin encapsulant 104, and that the light-emitting surface 121 is entirely exposed. However, there is no problem even if part of the light-emitting surface 121 is covered by the first resin encapsulant 104. For example, as illustrated in FIG. 14 and FIG. 15, the first resin encapsulant 104 may overlap the outer edge of the light-emitting surface 121 of the light-emitting element 102, or may be scattered on the plane of the light-emitting surface 121.

The light-emitting device of the present disclosure has chromaticity uniformity and high reliability, and is particularly useful as a light-emitting device including a resin encapsulant which transmits light from a light-emitting element, and a method for manufacturing the light-emitting device.

What is claimed is:

1. A light-emitting device, comprising:
a substrate;
a light-emitting element mounted on the substrate, with a surface opposite to a light-emitting surface facing the substrate;
a first resin encapsulant which covers the light-emitting element such that at least part of the light-emitting surface is exposed; and
a second resin encapsulant provided on and in contact with the first resin encapsulant and the light-emitting surface, wherein
the first resin encapsulant contains a light reflective material, and
the second resin encapsulant includes a first layer containing a light wavelength conversion material which absorbs first light and emits second light, and a transparent resin layer provided under the first layer and in contact with the light-emitting surface.

2. The light-emitting device of claim 1, wherein
the second resin encapsulant includes a second layer provided on the first layer and containing a light diffusing material which diffuses the first light and the second light.

3. The light-emitting device of claim 1, further comprising:
a protection element mounted on the substrate, wherein
the first resin encapsulant covers an upper surface of the protection element.

4. A light-emitting device, comprising:
a substrate;
a light-emitting element mounted on the substrate, with a surface opposite to a light-emitting surface facing the substrate;
a first resin encapsulant which covers the light-emitting element such that at least part of the light-emitting surface is exposed; and
a second resin encapsulant provided on and in contact with the first resin encapsulant and the light-emitting surface, wherein
the first resin encapsulant contains a light reflective material, and
the second resin encapsulant includes a first layer containing a light wavelength conversion material which absorbs first light and emits second light, and having a groove which surrounds the light-emitting element, and a light reflective layer containing a light reflective material and filling the groove.

5. The light-emitting device of claim 4, wherein
the second resin encapsulant includes a second layer provided on the first layer and containing a light diffusing material which diffuses the first light and the second light.

6. The light-emitting device of claim 4, wherein
the first layer contains a light diffusing material which diffuses the first light and the second light.

7. A light-emitting device, comprising:
a substrate;
a light-emitting element mounted on the substrate, with a surface opposite to a light-emitting surface facing the substrate;
a first resin encapsulant which covers the light-emitting element such that at least part of the light-emitting surface is exposed; and
a second resin encapsulant provided on and in contact with the first resin encapsulant and the light-emitting surface, wherein
the first resin encapsulant contains a light reflective material, and
the second resin encapsulant includes a third layer containing a light wavelength conversion material which absorbs first light and emits second light, and a light diffusing material which diffuses the first light and the second light.

8. The light-emitting device of claim 7, wherein
the second resin encapsulant includes a transparent resin layer provided under the third layer and in contact with the light-emitting surface.

9. The light-emitting device of claim 7, wherein
the second resin encapsulant includes a fourth layer provided on the third layer and containing a light diffusing material.

10. The light-emitting device of claim 7, further comprising:
a protection element mounted on the substrate, wherein
the first resin encapsulant covers an upper surface of the protection element.
